(19) United States
(12) Patent Application Publication
(10) Pub. No.: US 2011/0266671 A1
(43) Pub. Date: Nov. 3, 2011

(54) SUBSTRATE FOR A SEMICONDUCTOR PACKAGE AND MANUFACTURING METHOD THEREOF

(75) Inventors: Kwang Seop Youm, Chungcheongbuk-do (KR); Young Hwan Shin, Daejeon (KR); Kyoung Ro Yoon, Daejeon (KR); Sang Duck Kim, Chungcheongbuk-do (KR); Kyo Min Jung, Daejeon (KR); Bong Hie Jung, Chungcheongbuk-do (KR)

(73) Assignee: SAMSUNG ELECTRO-MECHANICS CO., LTD., Gyunggi-do (KR)

(21) Appl. No.: 12/949,267

(22) Filed: Nov. 18, 2010

(30) Foreign Application Priority Data
May 3, 2010 (KR) 1020100041542
Jul. 14, 2010 (KR) 1020100068104

(51) Int. Cl. H01L 23/48; H01L 21/60

(52) U.S. Cl. 257/738; 438/125; 257/E23.011; 257/E21.506

(57) ABSTRACT

Disclosed herein are a substrate for a semiconductor package and a manufacturing method thereof. The substrate for the semiconductor package, which has a single-sided substrate structure including circuit patterns having a connection pad formed on only an electronic component mounting surface, can directly connect a connection pad on the top of the substrate to external connection terminals on the bottom of the substrate through a connection via formed of a metal plating layer formed in an inner wall of the via hole and a conductive metal paste filled in the via hole.

### CROSS REFERENCE TO RELATED APPLICATION

This application claims the benefit of Korean Patent Application No. 10-2010-0068104, filed on Jul. 14, 2010, entitled “Substrate For A Semiconductor Package And Manufacturing Method Thereof”, Korean Patent Application No. 10-2010-0041542, filed on May 3, 2010, entitled “Substrate For A Semiconductor Package And Manufacturing Method Thereof”, which are hereby incorporated by reference in its entirety into this application.

### BACKGROUND OF THE INVENTION

1. Technical Field

The present invention relates to a substrate for a semiconductor package and a manufacturing method thereof.

2. Description of the Related Art

A semiconductor mounting circuit substrate on which a DDR memory is mounted has been generally used by being formed as a single circuit. Recently, as a demand for a multi-functional ICs have increased, a flip-chip mounting scheme has been used instead of an existing wire bonding scheme and at the same time, the substrate has also required a circuit layer having two sides or more, instead of a board on chip (BOC) using a single-sided circuit layer.

Hereinafter, a method for manufacturing a double-sided circuit substrate for a semiconductor package according to a prior art will be described with reference to FIGS. 1 to 8.

Referring to FIG. 1, a double-sided copper clad laminate 10 on which copper clad layers 12 are stacked on both surfaces of an insulating layer 11 is first prepared. Thereafter, as shown in FIG. 2, via holes 13 penetrating though the copper clad laminate 10 by mechanical drilling or laser are formed.

Next, as shown in FIG. 3, a seed layer of about 1 μm or less is formed by performing electroless copper plating and a copper playing layer 14 is formed by performing electro copper plating to have a plating thickness of about 10 μm or more and then, as shown in FIG. 4, is patterned according to a predetermined pattern to form circuit patterns 15 on both sides of the insulating layer.

FIG. 5 is an enlarged view for explaining in detail the double-sided circuit substrate structure of FIG. 4. In the substrate for the semiconductor package according to the prior art, inter-layer circuits are electrically connected to each other through a via A having a plating layer B formed in an inner wall of a hole through electroless and electro plating.

Top circuit patterns C1 and C2 are provided with a connection pad C2 connected to electronic components and circuit patterns on the bottom are provided with a solder ball pad D on which an external connection terminal such as a solder ball is mounted.

The hole diameter of the via A is generally set to be about 0.2 mm or less due to limitations in a manufacturing process, or the like.

Thereafter, referring to FIG. 6, a solder resist layer 16 having an opening is formed in order to expose the connection pad among the top circuit patterns and the solder ball pad among the bottom circuit patterns. As shown in FIG. 7, a surface treatment layer 17 is formed by performing a typical surface treatment process, such as Ni/Au plating, on the exposed connection pad and the solder ball pad.

Finally, as shown in FIG. 8, electronic components (ICs) are mounted on the top of the substrate and are connected to the connection pad through a connection member, such as the wire bonding, and a solder ball 18 is formed on the solder ball pad exposed on the bottom of the substrate.

As described above, in order to implement a semiconductor mounting circuit substrate having two sides or more, the fine via machining, the plating in hole, or the like, are needed. However, the more the number of vias, the higher the cost becomes. In addition, the hole diameter of the via is set to be 0.2 mm or less due to the limitations in the manufacturing process, such that the heat radiating characteristics are relatively reduced and the electrical resistance is high. Further, there is a limitation in lowering the thickness of the circuit substrate by forming circuits on both surfaces.

### SUMMARY OF THE INVENTION

The present invention has been made in an effort to provide a single-sided circuit substrate and a manufacturing method thereof capable of reducing manufacturing costs while receiving the increased I/Os similar to the double-sided circuit substrate according to the prior art.

Further, the present invention has been made an effort to provide a substrate for a semiconductor package and a manufacturing method thereof capable of lowering electrical resistance while improving heat-radiating characteristics by making a hole diameter of a via large, as compared to existing products.

In addition, the present invention has been made in an effort to provide a substrate for a semiconductor package and a manufacturing method thereof capable of improving the number of substrate stacks by forming a large-diameter via, as compared to existing products.

A substrate for a semiconductor package according to a first preferred embodiment of the present invention includes: an insulating layer that has a first surface and a second surface and is formed with a via hole penetrating through the insulating layer; a connection via that includes a metal plating layer formed in an inner wall of the via hole and a conductive metal paste filled in the via hole; a circuit patterns that are formed on the first surface of the insulating layer and includes a connection pad formed on the connection via of the first surface; and external connection terminals that are formed on the connection via of the second surface of the insulating layer and are electrically connected to the connection pad of the first surface through the connection via.

Preferably, the metal plating layer may be an electroless metal plating layer.

Preferably, the metal plating layer may have a thickness of 3 μm or less.

The substrate for a semiconductor package may further include a solder resist layer that is formed on the first surface and the second surface of the insulating layer and has an opening exposing the connection pad and the surface of the connection via of a portion where the external connection terminals will be formed.

The substrate for a semiconductor package may further include a surface treatment layer that is formed on the connection pad and the connection via that are exposed through the opening of the solder resist layer.

The substrate for a semiconductor package may further include electronic components that are mounted on the solder resist layer on the first surface of the insulating layer and are electrically connected to the connection pads through the connection members.

The conductive metal paste may be selected from a group consisting of Cu, Ag, Sn, Pb, an alloy thereof, or a combination thereof.

The insulating layer may be a resin insulating layer or a ceramic insulating layer.

Preferably, the external connection terminal may be a solder ball.

A method for manufacturing a substrate for a semiconductor package according to a second preferred embodiment of the present invention includes: preparing an insulating layer that has a first surface and a second surface and a via hole penetrating through the insulating layer and includes a circuit pattern having a connection pad formed on the via hole of the first surface; forming a metal plating layer in an inner wall of the via hole; forming a connection via by filling a conductive metal paste in the via hole formed with the metal plating layer; and forming external connection terminals on a connection via of the second surface of the insulating layer to be electrically connected to the connection pad of the first surface through the connection via.

The preparing the insulating layer may include: preparing an insulating layer having a first surface and a second surface; forming a via hole penetrating through the insulating layer; stacking a metal layer on the first surface of the insulating layer on which the via hole is formed; and forming circuit patterns on the first surface of the insulating layer by using the metal layer.

The preparing the insulating layer having the first surface and the second surface may be performed by removing the double-sided metal clad of the double-sided metal clad laminate on which the metal clad is stacked on both surfaces of the insulating layer.

The stacking the metal layer may be performed by stacking the metal layer on the first surface of the insulating layer, interposing the adhesive therebetween and then, removing the adhesive formed on the bottom of the via hole.

The forming the metal plating layer in the inner wall of the via hole may include: forming a metal plating layer over the via hole and the insulating layer having the circuit pattern formed on the first surface thereof by an electroless metal plating; and removing unnecessary portions of the metal plating layer to form the metal plating layer in the inner wall of the via hole.

The method for manufacturing a substrate for a semiconductor package may further include: after the forming the connection via, forming a solder resist layer that is formed on the first surface and the second surface of the insulating layer and has an opening exposing the connection pad and the surface of the connection via of a portion where the external connection terminals will be formed.

The method for manufacturing a substrate for a semiconductor package may further include: after the forming the solder resist layer, forming a surface treatment layer formed on the connection pad and the connection via that are exposed through the opening of the solder resist layer.

The method for manufacturing a substrate for a semiconductor package may further include: after the forming the solder resist layer, mounting electronic components on the solder resist layer on the first surface of the insulating layer and electrically connecting the electronic components to the connection pads through the connection members.

### BRIEF DESCRIPTION OF THE DRAWINGS

FIGS. 1 to 8 are cross-sectional views for schematically explaining a process of manufacturing a substrate for a semiconductor package according to a prior art;

FIG. 9 is a cross-sectional view for schematically explaining a structure of a substrate for a semiconductor package according to a preferred embodiment of the present invention; and

FIGS. 10 to 19 are cross-sectional views for schematically explaining a method for manufacturing a substrate for a semiconductor package according to a preferred embodiment of the present invention.

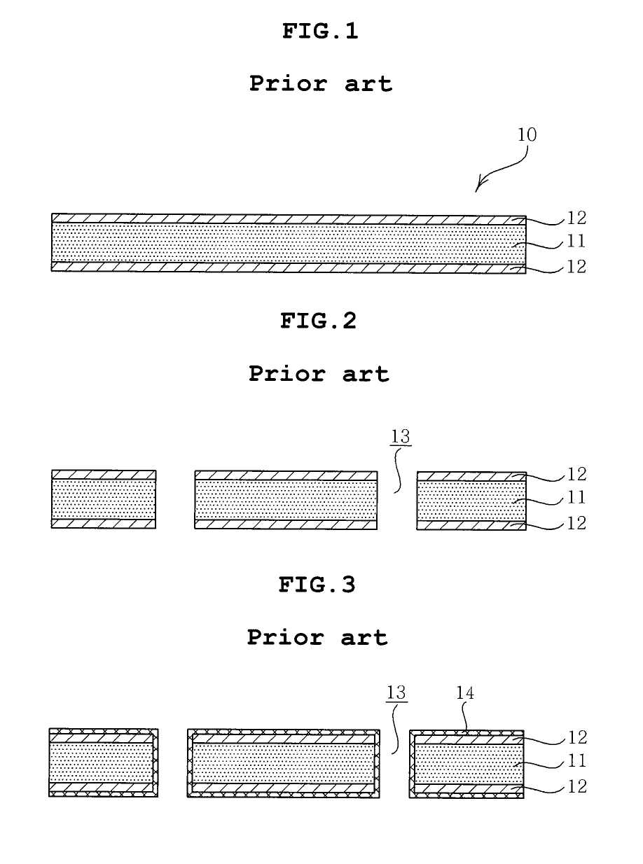

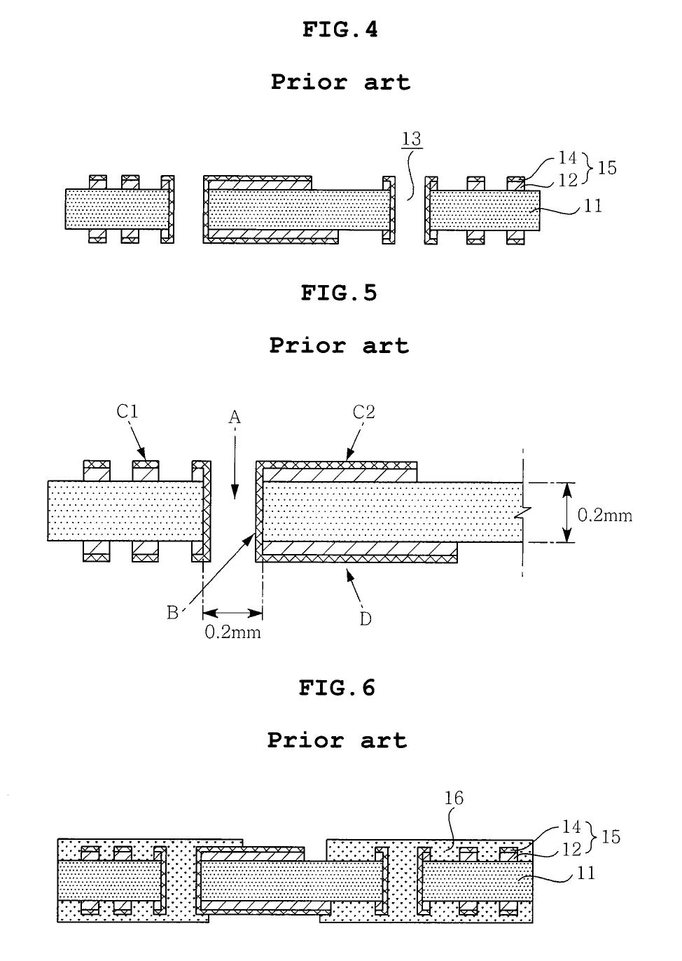

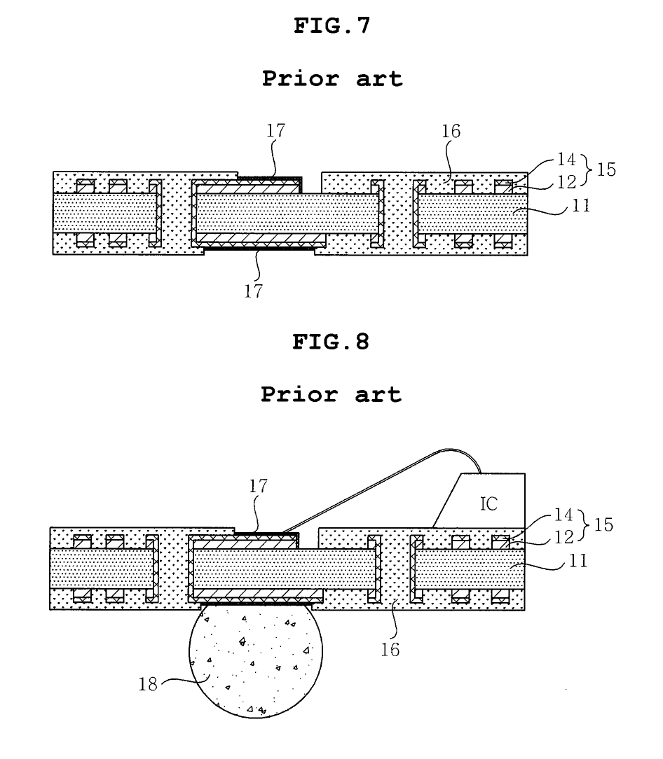

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first,” “second,” and so on are used to distinguish one element from another element, and the elements are not defined by the above terms.

Hereinafter, preferred embodiments of the present invention will be described in detail with reference to the accompanying drawings.

### Substrate for Semiconductor Package

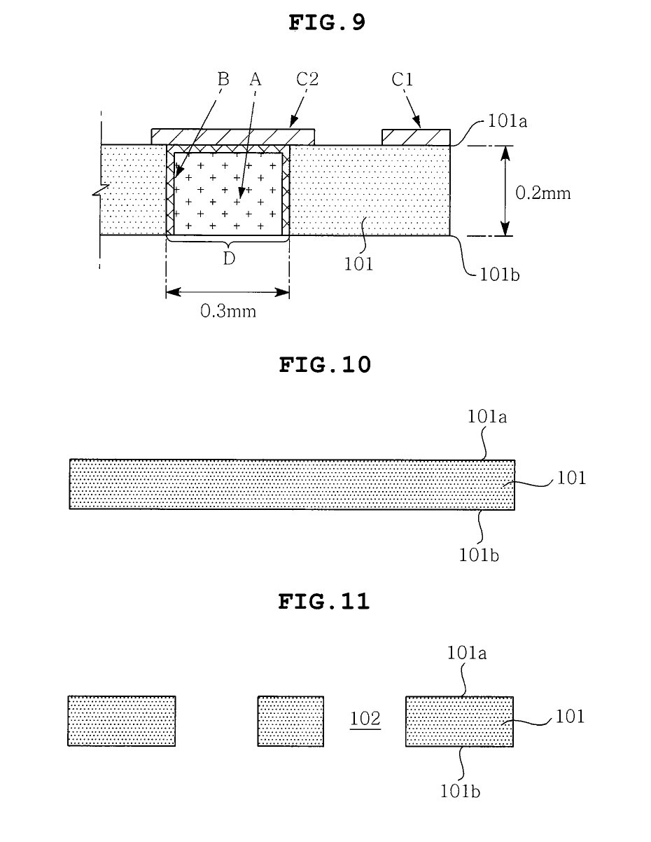

FIG. 9 is a cross-sectional view schematically showing a structure of a substrate for a semiconductor package according to a preferred embodiment of the present invention.

Referring to FIG. 9, a substrate for a semiconductor package according to an embodiment of the present invention has a single-sided substrate structure including circuit patterns C1 and C2 having a connection pad C2 formed on only an electronic component mounting surface. In this configuration, a metal plating layer B is in an inner wall of a via hole as an auxiliary channel and a connection via is formed by filling a conductive metal paste A in the via hole, such that the connection pad C2 on the top of the substrate can be directly connected to external connection terminals (not shown) formed on a connection via D on the bottom of the substrate through the connection via without having a separate circuit pattern including the connection pad formed on the bottom of the substrate.

In more detail, the substrate for the semiconductor package according to the embodiment of the present invention includes: an insulating layer 101 that has a first surface 101a and a second surface 101b and is formed with a via hole penetrating through the inside of the insulating layer; a connection via that includes the metal plating layer B formed in the inner wall of the via hole and the conductive metal paste A filled in the via hole; the circuit patterns C1 and C2 that are formed on the first surface 101a of the insulating layer 101 and the connection pad C2 formed on the connection via of the first surface 101a; and the external connection terminals (not shown) that are formed on the connection via D of the second surface 101b of the insulating layer 101 and are electrically connected to the connection pad C2 of the first surface 101a through the connection via.

Preferably, the metal plating layer B may be formed of an electroless metal plating layer. It is preferable that the thickness of the metal plating layer B is set to be about 3 μm or less in terms of economical efficiency. Currently, in order to satisfy electrical characteristics of a printed circuit board, the thickness of the plating layer included in the via hole is set to be 8 μm at a minimum. Therefore, it requires much time and cost to form the plating layer having the above thickness. On the other hand, the present invention can obtain sufficient electrical characteristics and heat-radiating characteristics even when the thickness of the metal plating layer B is set to be 3 μm or less.

Preferably, in order to improve the heat-radiating characteristics and the electrical characteristics as compared to the existing circuit substrate, the diameter of the via hole may be set to be about 0.3 mm or more.

The total thickness of the insulating layer 101 may be generally set to be about 0.2 mm, but may be properly controlled as needed.

As the insulating layer, a resin insulating layer used as the insulating layer of the printed circuit board or a ceramic insulating layer used as the insulating layer of the semiconductor substrate may be used. As the resin insulating layer, thermosetting resin such as epoxy resin, thermoplastic resin such as polyimide, or resins made by impregnating a stiffener such as glass fiber, inorganic filler, or the like, in the above-mentioned resins may be used and thermosetting resin and/or photocurable resin, etc., may also be used, but is not specifically limited thereto.

If the metal of the metal plating layer and the circuit patterns can be used as a metal for a circuit in a circuit substrate field, they can be applied without any limitation. In the printed circuit board, copper is generally used.

An example of the conductive metal paste may include, for example, Cu, Ag, Sn, Pb, an alloy thereof, or a combination of two or more thereof, but is not specifically limited thereto. In addition to the above-mentioned metal components, it can be appreciated to those skilled in the art that binder, other resin components, or the like, may be further provided in order to give adhesion.

Optionally, a solder resist layer having an opening exposing the connection pad C2 and the surface of the connection via D of a portion where the external connection terminals will be formed may be further formed on the first surface 101a and the second surface 101b of the insulating layer 101.

The solder resist layer, which protects the circuit patterns on the outermost layer and is formed for electrical isolation, is formed with the opening to expose the pad parts C2 and D on the outermost layer connected to external devices.

In addition, a surface treatment layer may be optionally formed on the connection pad C2 and the connection via D that are exposed through the opening of the solder resist layer.

If the surface treatment layer has been known to those skilled in the art, it is not specifically limited thereto. For example, the surface treatment layer may be formed by electro gold plating, electroless gold plating, organic soderability preservative (OSP), electroless tin plating, electroless silver plating, direct electroless gold (DIG) plating, hot air solder leveling (HASL), or the like. The pad parts C2 and D formed by the above-mentioned process are used as a pad for wire bonding or a pad for a bump according to the purpose or may be used as a pad for a solder ball ring for mounting external connection terminals such as the solder ball.

In addition, the solder resist layer on the first surface 101a of the insulating layer 101 may further provide electronic components (ICs) electrically connected to the connection pad C2 through the connection members, such as, for example, wire, bump, or the like.

### Method for Manufacturing Substrate for Semiconductor Package

FIGS. 10 to 19 are cross-sectional views for schematically explaining a method for manufacturing a substrate for a semiconductor package according to a preferred embodiment of the present invention.

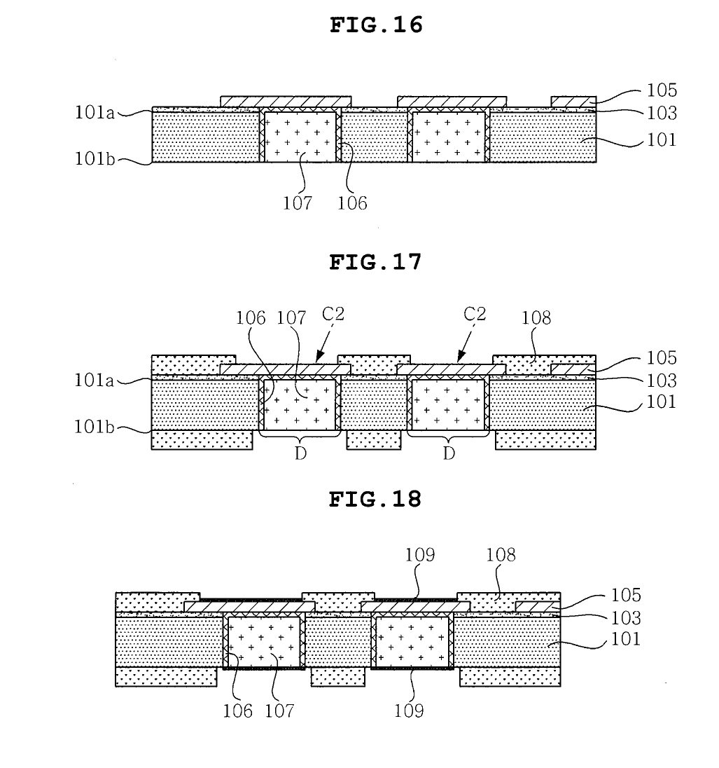

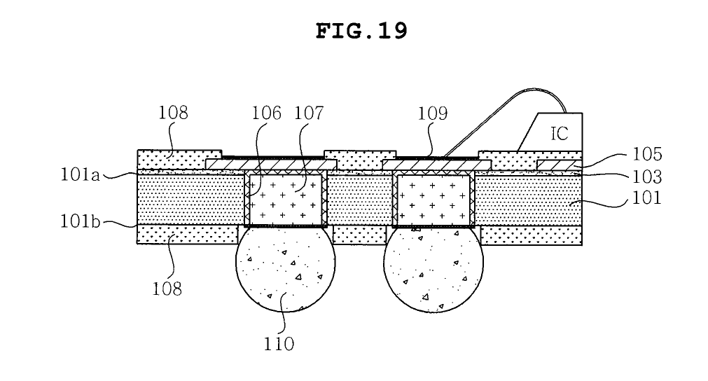

Referring to FIGS. 10 to 19, a method for manufacturing a substrate for a semiconductor package according to an embodiment of the present invention includes: preparing, on the first surface 101a, the insulating layer 101 that has the first surface 101a and the second surface 101b and the via hole 102 penetrating through the inside of the insulating layer and includes the circuit pattern 105 having the connection pad C2 formed on the via hole 102 of the first surface 101a (see FIGS. 10 to 14); forming the metal plating layer 106 in the inner wall of the via hole 102 (see FIGS. 15 and 16); forming the connection via by filling the conductive metal paste 107 in the via hole 102 formed with the metal plating layer 106 (see FIG. 16); and forming the external connection terminal 110 on the connection via D of the second surface 101b of the insulating layer 101 to be electrically connected to the connection pad C2 of the first surface 101a through the connection via (see FIG. 19).

Herein, the method for manufacturing the substrate for the semiconductor package may optionally further include: forming the solder resist layers 108 having the opening exposing the pad parts C2 and D on both surfaces of the insulating layer 101 (see FIG. 17); and/or forming the surface treatment layer 109 on the exposed pad parts C2 and D (see FIG. 18); and/or mounting the electronic components (ICs) on the solder resist layer 108 on the first surface 101a of the insulating layer 101 and electrically connecting them to the connection pad C2 through the connection member (see FIG. 19).

Hereinafter, the method for manufacturing the substrate for the semiconductor package according to the preferred embodiment of the present invention will be described with reference to FIGS. 10 to 19.

First, as shown in FIGS. 10 to 14, the via hole 102 and the insulating layer 101 having the circuit pattern 105 formed on the first surface 101a thereof are prepared.

In more detail, as shown in FIG. 10, the insulating layer 101 having the first surface 101a and the second surface 101b is prepared. As the insulating layer 101, the resin insulating layer used as the insulating layer of the printed circuit board or the ceramic insulating layer used as the insulating layer of the semiconductor substrate may be used. As the resin insulating layer, thermosetting resin such as epoxy resin, thermoplastic resin such as polyimide, or resin made by impregnating a stiffener such as glass fiber, inorganic filler, or the like, in the above-mentioned resins may be used, but is not specifically limited thereto.

In this case, it is preferable that the insulating layer 101 formed by removing a double-sided metal clad from a double-sided metal clad laminate in which metal dads are stacked on both surfaces of the insulating layer is used in terms of improvement of adhesion with the metal for the circuit in the subsequent processes, but is not specifically limited thereto. If the metals of the metal clad can be generally used as the conductive metal in the circuit substrate field, they can be used without limitations. In the printed circuit board, the copper clad is generally used.

Then, as shown in FIG. 11, the via hole 102 penetrating through the insulating layer 101 is formed.

The via hole 102 may be machined by drilling, such as a computer numerical control (CNC) drill, CO₂ or Yag laser drill. After machining the hole, it is preferable to perform deburring and desmear in order to remove the burr and smear of the copper clad caused by drilling.

In this case, in order to improve the heat-radiating characteristics and the electrical characteristics against the existing circuit substrate, it is preferable that the diameter of the via hole 102 is set to be about 0.3 mm or more.

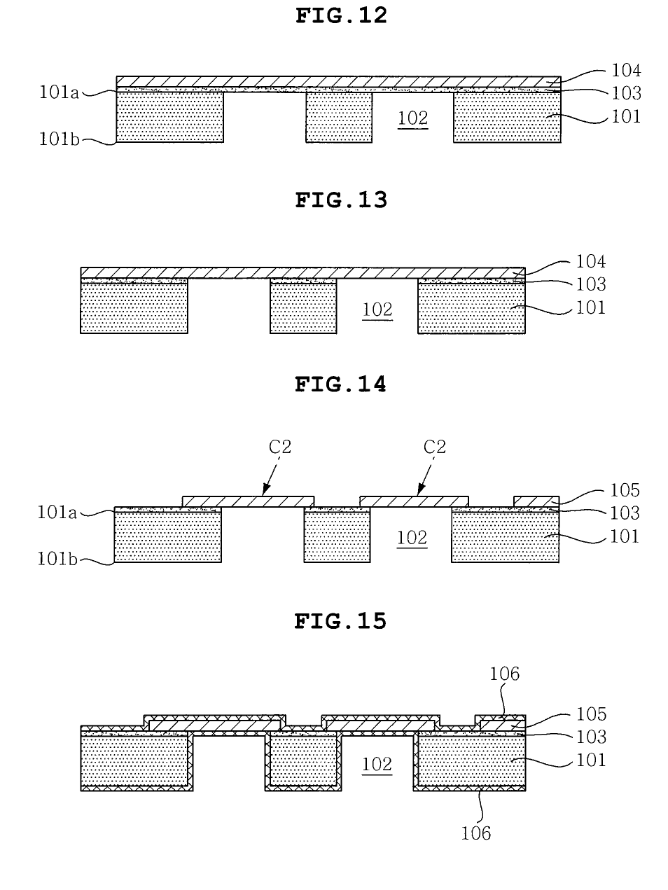

Thereafter, as shown in FIGS. 12 to 14, the circuit pattern 105 is formed on the first surface 101a of the insulating layer 101.

In more detail, as shown in FIG. 12, the metal layer 104 is stacked on the first surface 101a of the insulating layer 101, interposing the adhesive 103 therebetween, and then, as shown in FIG. 13, the adhesive 103 formed on the bottom of the via hole 102 is removed. If the metal layer can be used as the metal for the circuit in the circuit substrate field, it can be used without limitations. In the printed circuit board, the copper clad layer is generally used. Further, the adhesive 103 may not be used according to the kind of actually used insulating layer 101 and the detailed stacking process.

Then, as shown in FIG. 14, the circuit pattern 105 is formed on the first surface 101a of the insulating 101 by patterning the metal layer 104 using, for example, a tenting mechanism. The circuit pattern 105 includes the connection pad C2 formed on the via hole 102 of the first surface 101a.

In the embodiment, although the method of stacking the metal layer and then, forming the circuit pattern by the tenting process is described by way of example, those skilled in the art can sufficiently appreciate that all the circuit forming methods known in the general circuit substrate field can be applied without limitations, in addition to the above-mentioned methods as the method for forming the circuit patterns on one surface of the substrate on which the via hole is formed.

Next, as shown in FIGS. 15 and 16, the metal plating layer 106 is formed in the inner wall of the via hole 102.

In this case, the thickness of the metal plating layer 106 is set to be about 3 μm or less in terms of economical efficiency against efficiency. Currently, in order to satisfy electrical characteristics of a printed circuit board, the thickness of the plating layer included in the via hole is set to be 8 μm at a minimum. Therefore, it requires much time and cost to form the plating layer having the above thickness. On the other hand, the present invention can obtain sufficient electrical characteristics and heat-radiating characteristics even when the thickness of the metal plating layer 106 is set to be 3 μm or less.

In more detail, as shown in FIG. 15, the metal plating layer 106 may be formed over the via hole 102 and the insulating layer 101 having the circuit pattern 105 formed on the first surface thereof by electroless metal plating. If the metal of the metal plating layer 106 can be used as a metal for a circuit in a circuit substrate field, they can be applied without any limitation. In the printed circuit board, copper is generally used.

Thereafter, as shown in FIG. 16, unnecessary portions of the metal plating layer are removed to form the metal plating layer 106 in the inner wall of the via hole 102. Although the above figure shows the case in which the metal plating layer 106 formed on the circuit pattern 105 is also removed, only the metal plating layer 106 on the insulating layer 101 including the adhesive 103 may be optionally removed through the process such as the general flash etching, or the like, without removing the metal plating layer 106 on the circuit pattern 105.

Next, as shown in FIG. 16, the conductive metal paste 107 is filled in the via hole formed with the metal plating layer 106, thereby forming the connection via.

The conductive metal paste may include, for example, Cu, Ag, Sn, Pb, an alloy thereof, or a combination of two or more thereof, but is not specifically limited thereto.

Next, as shown in FIG. 17, the solder resist layer 108 having the opening exposing the connection pad C2 and the surface of the connection via D of a portion where the external connection terminals will be formed may be further formed on the first and second surfaces of the insulating layer 101.

The solder resist layer 108, which protects the circuit patterns on the outermost layer and is formed for electrical isolation, is formed with the opening to expose the pad parts C2 and D on the outermost layer connected to the external products.

The opening may be formed by the mechanical machining such as laser direct ablation (LDA), or the like.

Next, as shown in FIG. 18, the surface treatment layer 109 may be further formed on the connection pad C2 and the connection via D that are exposed through the opening of the solder resist layer 108.

If the surface treatment layer 109 has been known to those skilled in the art, it is not specifically limited thereto. For example, the surface treatment layer may be formed by electro gold plating, electroless gold plating, organic soderability preservative (OSP), electroless tin plating, electroless silver plating, direct electroless gold (DIG) plating, hot air solder leveling (HASL), or the like. The pad parts formed by the above-mentioned process are used as a pad for wire bonding or a pad for a bump according to the purpose or may be used as a pad for a solder ball ring for mounting the solder ball.

Next, as shown in FIG. 19, the external connection terminal 110 is formed on the connection via on the second surface of the insulating layer 101 and electrically connected to the connection pad of the first surface 101a through the connection via and the electronic components may be mounted on the solder resist layer 108 of the first surface of the insulating layer 101 and electrically connected to the connection pad through the connection members such as wire and/or bump. The external connection terminal 110 may be, for example, the solder ball.

As described above, the substrate for the semiconductor package according to the embodiment of the present invention has the single-sided circuit substrate structure where the circuit patterns are formed on only the electronic component mounting surface and may directly connect electrically the connection pad on the top to the external connection terminal on the bottom through the connection via without forming separate circuit patterns including the connection pad on the surface on which the external connection terminal is formed.

In addition, according to the preferred embodiment of the present invention, the plating layer in the inner wall of the via hole formed of the electroless metal plating layer and the electro metal plating layer is such that only the electroless metal plating layer is about 3 μm or less and the conductive metal paste is filled in the hole to form the connection via, thereby making it possible to increase the adhesion of the insulating layer and the conductive layer while improving the conductivity by lowering the resistance.

Further, according to the preferred embodiment of the present invention, the hole diameter of the via hole expands into a large diameter of about 0.3 mm or more and the number of substrate stacks is increased at the time of machining the via, thereby making it possible to improve the heat-radiating characteristics and the electrical characteristics while saving the machining cost.

According to a preferred embodiment of the present invention, the substrate for the semiconductor package can be manufactured as a single-sided substrate at lower manufacturing cost than the existing double-sided circuit substrate and the manufacturing cost thereof can be lowered and the adhesive characteristics and electrical characteristics thereof can be simultaneously improved by plating the inside of the via and filling the conductive metal paste for electrical connection, as compared to the case where only the existing plating is used.

In addition, according to the preferred embodiment of the present invention, the substrate for the semiconductor package has excellent heat-radiating characteristics and electrical characteristics due to the large hole diameter of the via, as compared to the existing products.

Although the preferred embodiments of the present invention have been disclosed for illustrative purposes, they are for specifically explaining the present invention and thus the substrate for a semiconductor package and the manufacturing method thereof according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A substrate for a semiconductor package, comprising:
an insulating layer that has a first surface and a second surface and is formed with a via hole penetrating through the insulating layer;
a connection via that includes a metal plating layer formed in an inner wall of the via hole and a conductive metal paste filled in the via hole;
circuit patterns that are formed on the first surface of the insulating layer and includes a connection pad formed on the connection via of the first surface; and
external connection terminals that are formed on the connection via of the second surface of the insulating layer and are electrically connected to the connection pad of the first surface through the connection via.

2. The substrate for a semiconductor package as set forth in claim 1, wherein the metal plating layer is an electroless metal plating layer.

3. The substrate for a semiconductor package as set forth in claim 1, wherein the metal plating layer has a thickness of 3 μm or less.

4. The substrate for a semiconductor package as set forth in claim 1, further comprising a solder resist layer that is formed on the first surface and the second surface of the insulating layer and has an opening exposing the connection pad and the surface of the connection via of a portion where the external connection terminals are formed.

5. The substrate for a semiconductor package as set forth in claim 4, further comprising a surface treatment layer that is formed on the connection pad and the connection via that are exposed through the opening of the solder resist layer.

6. The substrate for a semiconductor package as set forth in claim 4, further comprising electronic components that are mounted on the solder resist layer on the first surface of the insulating layer and are electrically connected to the connection pads through the connection members.

7. The substrate for a semiconductor package as set forth in claim 1, wherein the conductive metal paste is selected from a group consisting of Cu, Ag, Sn, Pb, an alloy thereof, or a combination thereof.

8. The substrate for a semiconductor package as set forth in claim 1, wherein the insulating layer is a resin insulating layer or a ceramic insulating layer.

9. The substrate for a semiconductor package as set forth in claim 1, wherein the external connection terminal is a solder ball.

10. A method for manufacturing a substrate for a semiconductor package, comprising:
preparing an insulating layer that has a first surface and a second surface and a via hole penetrating through the insulating layer and includes a circuit pattern having a connection pad formed on the via hole of the first surface;
forming a metal plating layer in an inner wall of the via hole;
forming a connection via by filling a conductive metal paste in the via hole formed with the metal plating layer; and
forming external connection terminals on a connection via of the second surface of the insulating layer to be electrically connected to the connection pad of the first surface through the connection via.

11. The method for manufacturing a substrate for a semiconductor package as set forth in claim 10, wherein the preparing the insulating layer includes:
preparing an insulating layer having a first surface and a second surface;
forming a via hole penetrating through the insulating layer;
stacking a metal layer on the first surface of the insulating layer on which the via hole is formed; and
forming circuit patterns on the first surface of the insulating layer by using the metal layer.

12. The method for manufacturing a substrate for a semiconductor package as set forth in claim 11, wherein the preparing the insulating layer having the first surface and the second surface is performed by removing the double-sided metal clad of the double-sided metal clad laminate on which the metal clad is stacked on both surfaces of the insulating layer.

13. The method for manufacturing a substrate for a semiconductor package as set forth in claim 11, wherein the stacking the metal layer is performed by stacking the metal layer on the first surface of the insulating layer, interposing the adhesive therebetween and then, removing the adhesive formed on the bottom of the via hole.

14. The method for manufacturing a substrate for a semiconductor package as set forth in claim 10, wherein the forming the metal plating layer in the inner wall of the via hole includes:
forming a metal plating layer over the via hole and the insulating layer having the circuit pattern formed on the first surface thereof by an electroless metal plating; and
removing unnecessary portions of the metal plating layer to form the metal plating layer in the inner wall of the via hole.

15. The method for manufacturing a substrate for a semiconductor package as set forth in claim 10, wherein the metal plating layer has a thickness of 3 μm or less.

16. The method for manufacturing a substrate for a semiconductor package as set forth in claim 10, further comprising: after the forming the connection via, forming a solder resist layer that is formed on the first surface and the second surface of the insulating layer and has an opening exposing the connection pad and the surface of the connection via of a portion where the external connection terminals are formed.

17. The method for manufacturing a substrate for a semiconductor package as set forth in claim 16, further comprising: after the forming the solder resist layer, forming a surface treatment layer formed on the connection pad and the connection via that are exposed through the opening of the solder resist layer.

18. The method for manufacturing a substrate for a semiconductor package as set forth in claim 16, further comprising: after the forming the solder resist layer, mounting electronic components on the solder resist layer on the first surface of the insulating layer and electrically connecting the electronic components to the connection pads through the connection members.

19. The method for manufacturing a substrate for a semiconductor package as set forth in claim 10, wherein the conductive metal paste is selected from a group consisting of Cu, Ag, Sn, Pb, an alloy thereof, or a combination thereof.

20. The method for manufacturing a substrate for a semiconductor package as set forth in claim 10, wherein the external connection terminal is a solder ball.
